(19) United States
(12) Patent Application Publication
(10) Pub. No.: US 2005/0194655 A1
(43) Pub. Date: Sep. 8, 2005

(54) Solid-state imaging device

(75) Inventors: Yorito Sakano, Sakata-shi (JP); Akira Mizuguchi, Towoka-shi (JP)

Correspondence Address: EDWARDS & ANGELL, LLP, P.O. BOX 55874, BOSTON, MA, 02205, US

(73) Assignee: Seiko Epson Corporation

(21) Appl. No.: 11/030,693

(22) Filed: Jan. 5, 2005

(30) Foreign Application Priority Data
Jan. 5, 2004 (JP) 2004-000356

(51) Int. Cl. H01L 21/76; H01L 31/06

(52) U.S. Cl. 257/462

(57) ABSTRACT

A solid-state imaging device including a photoelectric conversion element PD and a transistor TM formed adjacent to the photoelectric conversion element, the solid-state imaging device comprising: a substrate 1 of one conductivity type; a first well 21 of reverse conductivity type formed on the substrate in a region for forming the photoelectric conversion element; a second well 4 of one conductivity type formed on the first well 21; a third well 21′ of reverse conductivity type formed on the substrate in a region for forming the transistor and adjacent to the first well; a fourth well 5 of one conductivity type formed on the third well 21′ and adjacent to the second well 4; a gate electrode 6 with an opening formed above the fourth well 5; a source 7 formed under the opening; a drain 8 formed away from the source 7 and electrically connected to the third well 21′; and at least a first diffusion layer 28 of one conductivity type formed between the source 7 and the third well 21′.

### BACKGROUND OF THE INVENTION

1. Field of the Invention

The present invention relates to a solid-state imaging device having the characteristics of high picture quality and low power consumption.

2. Related Art

As solid-state imaging devices with which cellular phones, etc., are equipped, there are charge coupled device (CCD) type image sensors and complementary metal-oxide semiconductor (CMOS) type image sensors. CCD type image sensors are excellent in picture quality, whereas CMOS type image sensors have low power consumption and low process costs. In recent years, metal-oxide semiconductor (MOS) type solid-state imaging devices of a threshold voltage modulation method have been proposed, which involve both high picture quality and low power consumption. The MOS type solid-state imaging devices of a threshold voltage modulation method are disclosed, for example, in Japanese Unexamined Patent Publication No. 2001-177085 (JP '085).

Image sensors obtain image outputs by arranging sensor cells in matrix and repeating their three states, that is, initialization, accumulation, and readout. In an image sensor disclosed in JP '085, each unit pixel has a light receiving diode for performing accumulation and a transistor for performing readout.

FIG. 11 is an exemplary sectional view showing an image sensor disclosed in JP '085.

The image sensor of FIG. 11 has a light receiving diode 111 and an insulated gate field effect transistor 112 disposed adjacent to each other for each unit pixel on a substrate 100. A gate electrode 113 of the transistor 112 is formed like a ring and a source region 114 is formed in the central opening portion of the gate electrode 113. A drain region 115 is formed around the gate electrode 113.

A charge (light-generated charge) generated by light that is incident through an opening area of the light receiving diode 111 is transferred into a P-type well region 116 under the gate electrode 113 and accumulated in a carrier pocket 117 formed in the region. The light-generated charge accumulated in the carrier pocket 117 alters a threshold voltage of the transistor 112. Thus signals (pixel signals) corresponding to the incident light can be taken out from the source region 114 of the transistor 112.

Incidentally, with respect to the device described in the JP '085, outputs of unit pixels arranged in the same column are taken out via a common source line. The voltages applied to gates of the transistor 112 are controlled for each line, thereby allowing selective readout from unit pixels of a certain line among those connected to a common source line. That is, relatively high gate voltages are applied to the transistors 112 of the unit pixels (selected pixels) from which readout is performed and relatively low gate voltages are applied to the transistors 112 of the other unit pixels (non-selected pixels) from which readout is not performed. The outputs of the transistors 112 to which high gate voltages are applied are higher than those of the transistors to which low gate voltages are applied, and thus outputs of the selected pixels can be obtained from the source line.

In a step for forming the source region 114 of the unit pixel shown in FIG. 11, phosphorus, for example, is implanted as an impurity. However, phosphorus has a high diffusion coefficient and therefore is diffused up to a portion (shaded area) located in the well region 116 and under the source region 114 by ion implantation for forming a source region. That is, the source region 114 encroaches on the well region 116, and a junction field effect transistor (that can be referred to as a “junction FET” hereinafter) is thereby formed in a region 122, which consists of the encroached portion and the adjacent portions, surrounded by the broken line.

Incidentally, it is possible to shallowly form a source region by implanting an impurity such as arsenic that has a larger mass number. In this case, however, the damage arising in implanting is great. As a result, an impurity with a larger mass number cannot be used for forming a source region.

FIG. 12 is an explanatory view showing an equivalent circuit of a unit pixel in FIG. 11. The drain region 115 around the gate electrode 113 and an N-type diffusion layer 118 are electrically connected, and a leakage path 125 from the drain region 115 to the N-type diffusion layer 118 is formed as shown in FIG. 12. Between the N-type diffusion layer 118 and the source region 114, JFET (junction transistor Tr1 in FIG. 12) is formed in the region 122.

FIG. 13 is a graph for showing concentration distributions in the source region 114 and the well region 116 thereunder, wherein the horizontal axis represents the depth of the substrate and the vertical axis represents the impurity concentration.

A curve a in FIG. 13 shows an impurity concentration distributions by impurity implantation in forming the well region 116. The curve a indicates that the impurity is implanted into the depth corresponding to the location for forming the well region 116 slightly apart from the surface of the substrate. Hence, the value of impurity concentration in the vicinity of the diffusion layer 118 of the well region 116 is relatively high.

A curve b shows impurity concentration distributions by impurity implantation in forming the source region 114. Ion implantation is performed so as to form the source region 114 in the vicinity of the surface of the substrate. As described above, however, an impurity is diffused to the extent of reaching a relatively deep area by ion implantation in forming the source region. The impurity concentration distributions of the source region 114 are thereby changed into those shown by a curve c in FIG. 13. As apparent from the comparison of curves a and c, in the portion of the well region 116 located under the source region 114, the concentration decreases under the influence of the impurity for forming a source region.

Incidentally, in the portion of the well region 116 other than that under the source region 114, such an encroachment caused by the source region 114 does not occur. That is, the carrier pocket 117 beneath the gate electrode 113 and the portion of the well region 116 located under the pocket are formed in P-type of a high concentration, while the portion of the well region 116 located under the source region 114 is encroached on. The junction FET is thereby formed by the encroached portion and the adjacent well region 116 in P-type of a high concentration.

As shown by the curve c, in the portion of the well region 116, which is located under the source region 114, an electric potential barrier remarkably decreases, and the junction FET (Tr1) is conducting even when the transistor 112 is not conducting, thereby making a leakage path 125 conduct from the drain region 115 to the source region 114. Thus in the device according to JP '085, the leakage path 125 by the JFET is formed between the drain region 115 and the source region 114, even when the transistor 112 is not conducting.

Consequently, the characteristics of the transistor 112 are affected particularly in the regions at a relatively low level of gate voltage Vg by a leakage current. By the effect of the leakage current, outputs of a non-selected pixel may be increased such that the accurate amount of accepted light cannot be detected. For example, there is a problem that when strong light is incident on a part of a pixel, vertical-line noise displayed in black (hereinafter referred to as black smear) is generated due to the effect of this strong light.

The present invention addresses such a problem and is intended to provide a solid-state imaging device that can prevent formation of a junction transistor to improve the characteristics of a modulation transistor and achieve high picture quality.

### SUMMARY OF THE INVENTION

A solid-state imaging device according one embodiment to the present invention is one including a photoelectric conversion element and a transistor formed adjacent to the photoelectric conversion element, the one comprising: a substrate of one conductivity type; a first well of reverse conductivity type formed on the substrate in a region for forming the photoelectric conversion element; a second well of one conductivity type formed on the first well; a third well of reverse conductivity type formed in a region for forming the transistor of the substrate and adjacent to the first well; a fourth well of one conductivity type formed on the third well and adjacent to the second well; a gate electrode with an opening formed above the fourth well; a source formed under the opening; a drain formed away from the source and electrically connected to the third well; and at least a first diffusion layer of one conductivity type formed between the source and the third well.

According to such a structure, a light-generated charge produced in the first well that is a region for forming the photoelectric conversion element is transferred from the second well to the fourth well. The threshold voltage of a channel of the transistor is controlled by a light-generated charge held in the fourth well, and therefore pixel signals corresponding to the light-generated charge are output from the transistor. The source region of the transistor is constituted of opposite conductive type. In the region for forming the transistor, the fourth well of one conductivity type and the third well of reverse conductivity type are formed. Between the source region and the third well, however, the first diffusion layer of one conductivity type is formed. The first diffusion layer can prevent a junction field effect transistor from being formed by the change of concentration in the fourth well. An electric potential barrier of the diffusion layer can also prevent a path of a leakage current from the third well to the source region from being formed. Therefore, high picture quality can be achieved. For example, an occurrence of black smear can be prevented.

Also, the first diffusion layer constitutes an electric potential barrier of the current path from the third well to the source.

According to such a structure, increasing the electric potential barrier under the source region can prevent a leakage current from arising.

Also, the solid-state imaging device comprises a second diffusion layer located under the gate electrode and in the fourth well, the layer having an impurity concentration higher than that of the fourth well.

According to such a structure, a light-generated charge is accumulated in the second diffusion layer. Between under the second diffusion layer and under the source region, a diffusion layer is formed, and therefore forming a path of a leakage current by a junction transistor under the second diffusion layer can be securely prevented.

Also, the first diffusion layer is formed to have a concentration substantially the same as or higher than that of the third well.

According to such a structure, the concentration of the first diffusion layer formed under the source region is sufficiently high. Therefore increasing the electric potential barrier for the current path from the third well to the source region can prevent a leakage current from flowing.

### BRIEF DESCRIPTION OF THE DRAWINGS

FIG. 1 is a sectional view showing a sectional form of a solid-state imaging device according to a first embodiment of the present invention.

FIG. 2 is a plan view showing a plan form of one sensor cell of a solid-state imaging device according to the present embodiment.

FIG. 3 is a circuit block diagram showing the whole structure of an element with an equivalent circuit.

FIG. 4 is a graph for explaining the cause of an occurrence of black smear.

FIG. 5 is a graph for explaining a concentration distribution in and under the source region, wherein the horizontal axis represents the depth of the substrate and the vertical axis represents the impurity concentration.

FIG. 6 is a graph showing the characteristics of a modulation transistor in a solid-state imaging device according to the present embodiment.

FIG. 7 is a process drawing for explaining a method for manufacturing an element.

FIG. 8 is a process drawing for explaining a method for manufacturing an element.

FIG. 9 is an explanatory view for explaining a manufacturing method according to a second embodiment of the present invention.

FIG. 10 is an explanatory view for explaining a manufacturing method according to a second embodiment of the present invention.

FIG. 11 is an exemplary sectional view showing an image sensor disclosed in JP '085.

FIG. 12 is an explanatory view showing an equivalent circuit of a unit pixel of FIG. 11.

FIG. 13 is a graph for showing concentration distributions in and under the source region, wherein the horizontal axis represents the depth of the substrate and the vertical axis represents the impurity concentration.

### DESCRIPTION OF THE PREFERED EMBODIMENTS

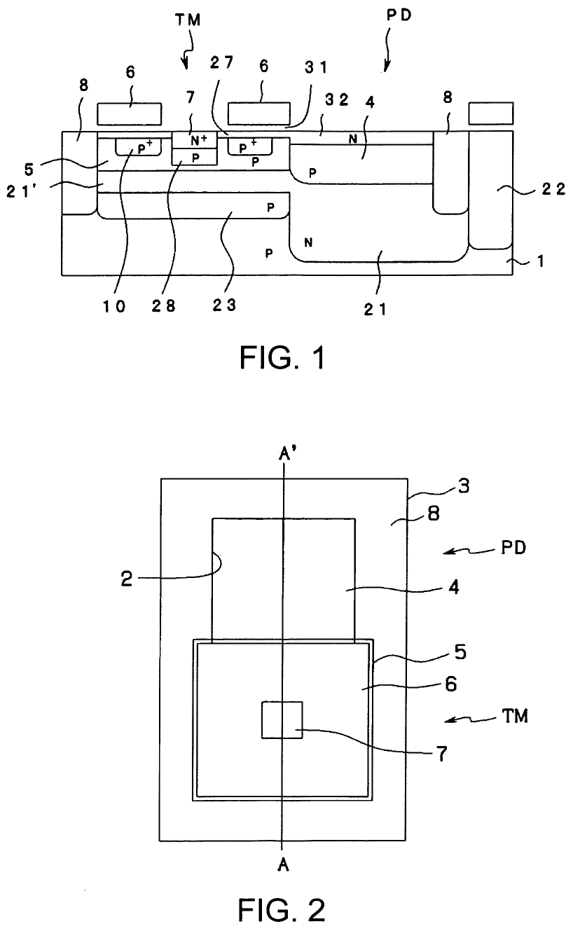

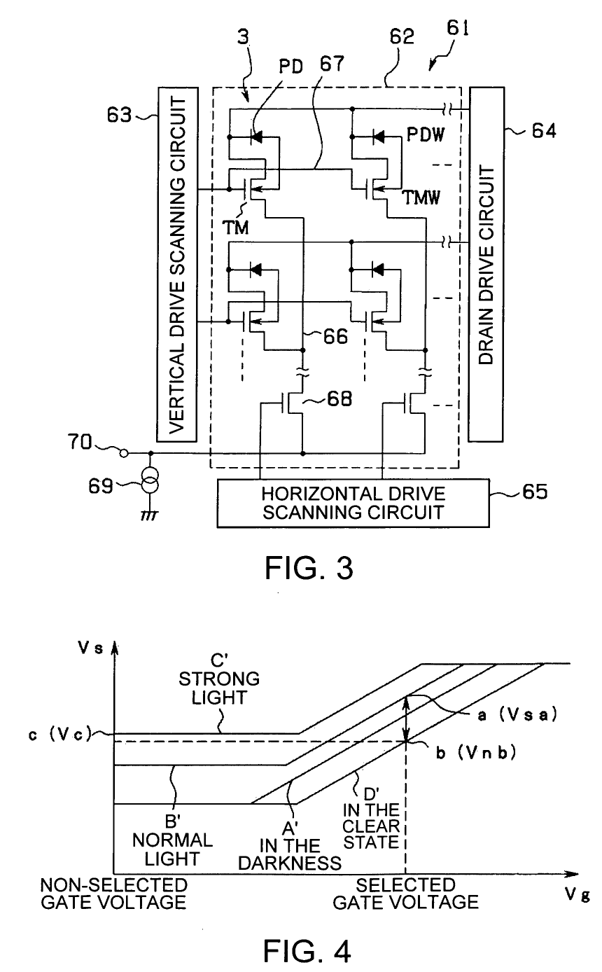

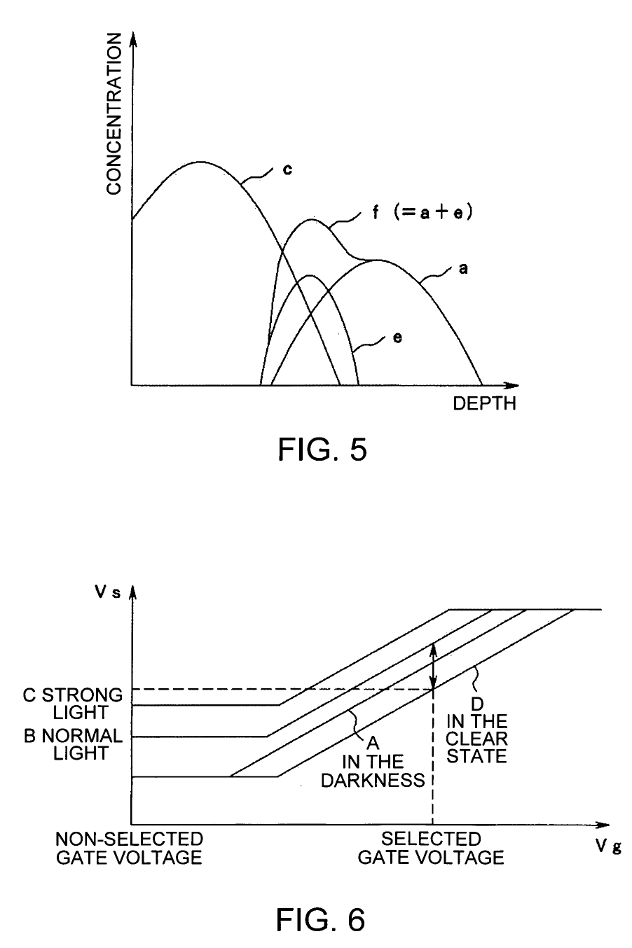

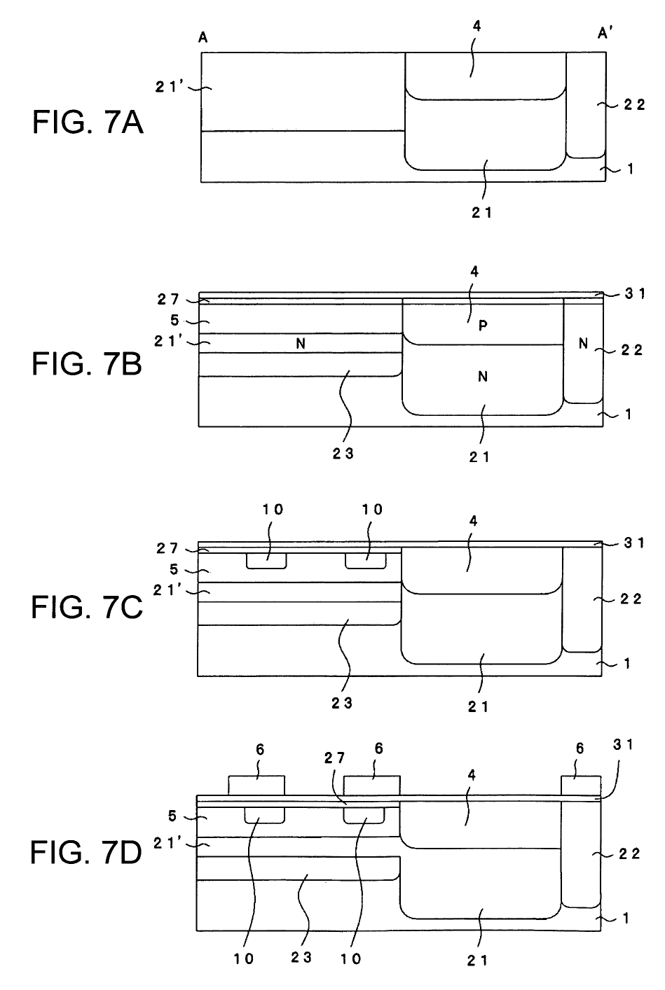

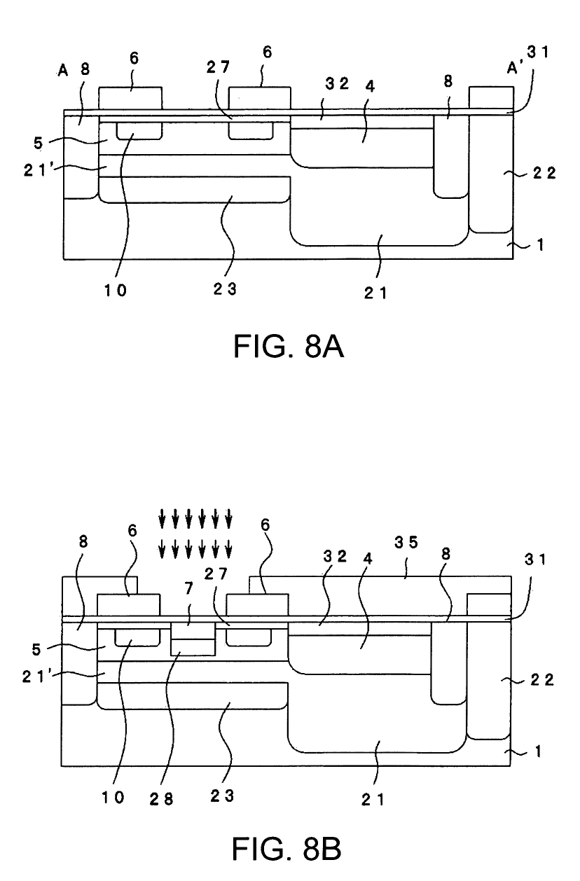

Embodiments of the present invention will now be described in detail below with reference to the drawings. FIGS. 1 to 8 are according to a first embodiment of the present invention. FIG. 1 is a sectional view showing a sectional form of a solid-state imaging device according to the present embodiment, FIG. 2 is a plan view showing a plan form of one sensor cell of a solid-state imaging device according to the present embodiment, and FIG. 3 is a circuit block diagram showing the whole structure of an element with an equivalent circuit. FIG. 4 is a graph for explaining the cause of an occurrence of black smear. FIG. 5 is a graph for explaining concentration distributions in and under the source region, wherein the horizontal axis represents the depth of the substrate and the vertical axis represents the impurity concentration. FIG. 6 is a graph showing the characteristics of a modulation transistor in a solid-state imaging device according to the present embodiment. FIGS. 7 and 8 are process drawings for explaining a method for manufacturing an element.

Structure of Sensor Cell

A solid-state imaging device according to the present embodiment has a sensor cell array composed of sensor cells, which are unit pixels, arranged in matrix. Each sensor cell collects and accumulates a light-generated charge produced corresponding to incident light, and outputs pixel signals at the level based of the accumulated light-generated charge. By arranging sensor cells in matrix, image signals of one screen are obtained.

Initially, the structure of each sensor cell will be described with reference to FIGS. 1 and 2. FIG. 2 shows one sensor cell. The present embodiment shows an example with the use of positive holes as a light-generated charge. In the case of using electrons as a light-generated charge, the similar construction can be adopted. Incidentally, FIG. 1 shows a sectional structure of a cell taken on line A-A′ of FIG. 2.

As shown in a plan view of FIG. 2, a photodiode PD and a modulation transistor TM are disposed adjacent to each other in a sensor cell 3 that is a unit pixel. As the modulation transistor TM, an N-channel depletion MOS transistor, for example, is used. The unit cell has, for example, a rectangular form.

In the photodiode PD formation region that is the photoelectric conversion element formation region, an opening region 2 is formed on the surface of the substrate 1, and a collection well 4 as the second well that is a P-type well having a region larger than the opening region 2 and collects a light-generated charge produced by the photoelectric conversion element is formed in a relatively shallow place of the surface of the substrate 1. On the collection well 4, an N-type diffusion layer 32 as a pinning layer is formed on the surface of the substrate 1.

Apart from the collection well 4 for a predetermined distance, a modulation well 5 as the fourth well, being a P-type well, to which a light-generated charge collected in the collection well 4 is transferred to control the modulation transistor TM, is formed in the modulation transistor TM formation region.

Above the modulation well 5, a gate in a ring form (ring gate) 6 is formed on the surface of the substrate 1, and a source region 7 that is a high concentration N-type region is formed in the area near the surface of the substrate 1 of the center opening portion of the ring gate 6. An N-type drain region 8 is formed around the ring grate 6. In a predetermined position of the drain region 8, a drain contact region (not shown) of an N⁺ layer is formed in the vicinity of the surface of the substrate 1.

The modulation well 5 controls a threshold voltage of a channel of the modulation transistor TM. In the modulation well 5, a carrier pocket 10 (FIG. 1) that is a P-type high concentration region and constitutes the second diffusion layer is formed under the ring gate 6. The modulation transistor TM consists of the modulation well 5, the ring gate 6, the source region 7, and the drain region 8, wherein a threshold voltage of the channel changes according to the charge accumulated in the modulation well 5 (carrier pocket 10).

The drain region 8 and the diffusion layer 32 are biased to the positive charge by applying a drain voltage. As a result, under the opening region 2 of the photodiode PD, a depletion layer expands from the interface between the diffusion layer 32 and the collection well 4 to the entire collection well 4, and reaches a N-type well 21 that is the first well. On the other hand, a depletion layer expands from the interface between the substrate 1 and the N-type well 21 to the entire N-type well 21, and reaches the collection well 4. In the depletion region, a light-generated charge is generated by the light that is incident through the opening region 2. As described above, the generated light-generated charge is collected in the collection well 4.

The charge collected in the collection well 4 is transferred to the modulation well 5 and held in the carrier pocket 10. A source potential of the modulation transistor TM thereby becomes one according to the amount of charge transferred to the modulation well 5, that is, the incident light to the photodiode PD.

Section of Sensor Cell

Further, the sectional structure of the sensor cell 3 will be described in detail with reference to FIG. 1.

FIG. 1 shows the modulation transistor TM formation region and the photodiode PD formation region adjacent thereto of one unit pixel (cell). An isolation region 22 is disposed between the photodiode PD formation region of one pixel and the modulation transistor TM formation region of the adjacent pixel.

At a relatively deep position of the substrate 1, the N-type well 21 is formed on the entire area of the P-type substrate 1. The P-type collection well 4 is formed on the N-type well 21 of the photodiode formation region. The N-type diffusion layer 32 that is a pinning layer is formed on the substrate surface side of the collection well 4. The N-type well 21 is formed to the extent of reaching the relatively deep position of the substrate.

On the other hand, in the modulation transistor TM formation region, a P-type buried layer 23 is formed on the substrate 1. The N-type well 21′ that constitutes the third well is limited to a relatively shallow position of the substrate by the P-type buried layer 23. The P-type modulation well 5 is formed on the N-type well 21′ located on the P-type buried layer 23. The carrier pocket 10 made by P⁺ diffusion is formed in the modulation well 5.

In the modulation transistor TM formation region, the ring gate 6 is formed on the substrate surface with a gate oxide film 31 therebetween and an N-type diffusion layer 27 that constitutes a channel is formed on the substrate surface under the ring gate 6. An N⁺-type diffusion layer is formed in the substrate surface at the center of the ring gate 6 to constitute the source region 7. An N-type diffusion layer is also formed in the substrate surface around the ring gate 6 to constitute the drain region 8. The N-type diffusion layer 27 that constitutes a channel is connected to the source region 7 and the drain region 8.

In the present embodiment, a P-type diffusion layer 28 as the first diffusion layer is formed beneath the source region 7. Forming the diffusion layer 28 beneath the source region 7 prevents the modulation well 5 from being encroached on by the source region 7. That is, a concentration of the portion of the modulation well 5 located under the source region 7 is made to be high so as to increase the electric potential barrier to electrons. The diffusion layer 28 can also prevent a junction FET made by the difference in concentration distribution from being formed in the portion of the modulation well 5 located under the source region 7.

Incidentally, the diffusion layer 28 is formed such that the size of its plane surface is approximately the same as that of the source region 7. However, the size of the plane surface of the diffusion layer 28 may be smaller than that of the source region 7, and conversely it may be larger than that of the source region 7.

Circuit Configuration of Entire Device

The circuit configuration of an entire solid-state imaging device according to the present embodiment will be described with reference to FIG. 3.

A solid-state imaging device 61 has a sensor cell array 62 including the sensor cell 3 in FIG. 2 and circuits 63 to 65 for driving each sensor cell 3 in the sensor cell array 62. The sensor cell array 62 is configured such that the cells 3 are arranged in matrix. The sensor cell array 62 includes the cells 3, for example, of 640×480 and a region (OB region) for optical black (OB). If including the OB region, the sensor cell array 62 is constituted of the cells 3, for example, of 712×500.

Each sensor cell 3 includes a photodiode PD for performing a photoelectric conversion and a modulation transistor TM for detecting and reading out light signals. The photodiode PD generates a charge (light-generated charge) according to incident light and the generated charge is collected in the collection well 4 (that corresponds to a connection point PDW in FIG. 3). The light-generated charge collected in the collection well 4 is transferred to and held in the carrier pocket 10 in the modulation well 5 (that corresponds to a connection point TMW in FIG. 3) for modulating a threshold of the modulation transistor TM.

In the modulation transistor TM, the state equivalent to the change of a back gate bias is achieved by holding a light-generated charge in the carrier pocket 10, and a threshold voltage of the channel varies according to the amount of the charge in the carrier pocket 10. A source voltage of the modulation transistor TM thereby becomes one that responds to the charge in the carrier pocket 10, that is, one that responds to the brightness of incident light of the photodiode PD.

Thus, each cell 3 exhibits operations such as accumulation, transfer, readout, and discharge by the application of drive signals to the ring gate 6, the source region 7, and the drain region 8 of the modulation transistor TM. Each part of the cell 3 is provided with signals from a vertical drive scanning circuit 63, a drain drive circuit 64, and a horizontal drive scanning circuit 65, as shown in FIG. 3. The vertical drive scanning circuit 63 provides scanning signals to a gate line 67 of each line and the drain drive circuit 64 applies a drain voltage to the drain region 8 of each column. The horizontal drive scanning circuit 65 also provides drive signals to a switch 68 connected to each source line 66.

Every cell 3 is disposed corresponding to intersection points between a plurality of source lines 66 arranged in the direction horizontal to the sensor cell array 62 and a plurality of gate lines 67 arranged in the direction vertical to the sensor cell array 62. In each cell 3 of each line arranged in the horizontal direction, the ring gate 6 of the modulation transistor TM is connected to the common gate line 67, while in each cell 3 of each column arranged in the vertical direction, the source of the modulation transistor TM is connected to the common source line 66.

By providing one of a plurality of gate lines 67 with ON signals (selected gate voltage), each cell commonly connected to the gate line 67 provided with the ON signals is simultaneously selected; pixel signals are output from each source of the selected cell via each source line 66. The vertical drive scanning circuit 63 provides the gate line 67 with ON signals sequentially shifting for one frame period. Pixel signals for one line from each cell of the line provided with ON signals are read out simultaneously from each source line 66 and supplied to each switch 68. The pixel signals for one line are sequentially output (line output) from the switch 68 for each pixel by the horizontal drive scanning circuit 65.

The switch 68 connected to each source line 66 is connected to a picture signal output terminal 70 through a common constant current source (load circuit) 69. As a result, the source of the modulation transistor TM of each sensor cell 3 is connected to the constant current source 69, thereby making a source follower circuit of the sensor cell 3.

Also in the above-described device of JP '085, source regions of all modulation transistors in the same column are commonly connected and voltage applied to the gates of the modulation transistors is controlled differently between selected lines and non-selected lines so as to detect the source voltage of the modulation transistors in a desired line. That is, the electric potential (Vg) of the gate electrodes is set to be high for all pixels of selected lines and the electric potential (Vg) of the gate electrodes of non-selected lines are made to be the ground potential.

In order to eliminate variations among unit pixels and various types of noise, in readout operations, following the readout operations of optical signals of selected lines, the pixels of the selected lines are initialized while leaving the state of providing the pixels of the non-selected lines with potential as it is, and subsequently a threshold voltage in the initialized state is read out. Then signals of the difference between the threshold voltage corresponding to the amount of light-generated charge and the threshold voltage in the initialized state is calculated, and thus a net optical signal component is output as picture signals.

The readout process in the device of JP '085 will be described with the use of FIG. 4 that shows the characteristics of the modulation transistor TM. The characteristics A′ to D′ of FIG. 4 indicate the characteristics of the modulation transistor TM in the darkness, when normal light is incident, when very strong light is incident, and in the clear state, respectively.

In FIG. 4, points a and b indicate a level Vsa, which is a level of pixel signals based on the pixel in the selected line on which light at the normal level is incident, and a level Vnb, which is a level of pixel signals by noise components after initializing the pixel signals, respectively. A point c also indicates a level Vc, which is a level of pixel signals based on the pixel of the non-selected line on which very bright light is incident. When the light of normal strength is incident, signals at the level of Vsa-Vnb (the range indicated by arrows) are obtained as pixel signals of the pixel of the selected line.

Now, in a predetermined column, light at the normal level be incident on the pixels of the selected lines and very bright light be incident on one of the pixels of the non-selected lines. The level of pixel signals before initialization based on the pixel of the selected line becomes Vsa. However, the level Vnb of pixel signals after initialization of the selected line is lower than the level Vc of pixel signals based on the pixel of the non-selected line when very strong light is incident. Since, in the same column, source regions are commonly connected, a higher level Vc is obtained as the level of pixel signals after initialization in reading out after initialization. That is, signals at the level of Vsa-Vc are output as pixel signals of the pixel of the selected column. The value of Vsa-Vc is relatively small; displays based on these pixel signals are black. All the outputs of each pixel connected to the source line 66 have relatively small values; screen displays show black smear in the vertical direction until the pixel on which very strong light is incident is initialized.

In contrast to this, in the present embodiment, formation of the diffusion layer 28 beneath the source region 7 prevents an occurrence of black smear in the case where strong light is incident.

Initially, description will be given for operations of detecting light and collecting a light-generated charge in the photodiode PD and reading out in the modulation transistor TM of the sensor cell 3.

A low gate voltage is applied to the ring gate 6 of the modulation transistor TM, and a voltage required for operations of the transistor, for example, a voltage (VDD) of 2 to 4 V is applied to the drain region 8. The N-type well 21 is thereby depleted. An electric field is also created between the drain region 8 and the source region 7.

The light that is incident through the opening region 2 of the photodiode PD is incident on the depleted N-type well 21, and a pair of an electron and a positive hole (light-generated charge) is thereby generated. The potential of the P-type collection well 4 is low because a high concentration P-type impurity is implanted to the well. The light-generated charge generated in the N-type well 21 is therefore collected into the collection well 4. Then the light-generated charge is transferred to the modulation well 5 to be accumulated in the carrier pocket 10.

By the light-generated charge accumulated in the carrier pocket 10, a threshold voltage of the modulation transistor TM changes. In this state, around 2 to 4V gate voltage (selected gate voltage), for example, is applied to the ring gate 6 of a selected pixel and around 2 to 4 V voltage VDD, for example, is applied to the drain region 8. In addition, a constant current is passed to the source region 7 of the modulation transistor TM through the constant current source 69. Thus a source follower circuit is created in the modulation transistor TM, whereby the source potential changes following the change of a threshold voltage of the modulation transistor TM and therefore the output voltage changes. That is, the output according to incident light is obtained.

In initializing, the charge remaining in the carrier pocket 10, the collection well 4, and the modulation well 5 is discharged. For example, a high positive voltage of 7 to 8V is applied to the drain region 8 and the ring gate 6 of the modulation transistor TM. Since the thickness of the N-type well 21′ under the modulation well 5 is thin and the high concentration P-type buried layer 23 is formed on the N-type well 21′ side of the substrate 1, a voltage applied to the ring gate 6 exerts an influence only upon the modulation well 5 and its adjacent region. That is, a drastic potential change occurs in the modulation well 5, whereby such a strong electric field as to sweep up a light-generated charge to the side of the substrate 1 is applied mainly to the modulation well 5, and as a result, the remaining light-generated charge is more reliably discharged into the substrate 1 with a low reset voltage.

After initializing, a non-selected gate voltage of relatively low value is applied to a ring gate of a non-selected pixel, while a selected gate voltage of relatively high value is applied to the ring gate 6 of a selected pixel. Then the signal output after initializing the selected pixel is obtained from the commonly connected source line 66.

In the present embodiment, the diffusive layer 28 is formed beneath the source region 7. This diffusive layer 28 keeps the area beneath the source region 7 in a sufficiently high concentration to prevent the modulation well 5 from being encroached by the source region 7. A sufficiently high electric potential barrier is thereby formed beneath the source region 7. A change of concentration does not occur in the P-type modulation well 5, and a junction FET is not formed. Therefore a current path from the N-type well 21′ to the source region 7 is not formed.

FIG. 5 shows concentration distributions in and under the source region. A curve a of FIG. 5 shows impurity concentration distributions by implanting an impurity in forming the P-type well 5. The curve a indicates that an impurity was implanted at the depth corresponding to a position for forming the P-type well 5 that is slightly away from the substrate surface.

A curve d shows impurity concentration distributions by implanting an impurity in forming the source region 7. Ion implantation is performed so as to form the source region 7 in the vicinity of the substrate surface. An impurity is diffused to the extent of a relatively deep area by ion implantation in forming the source region. A curve e shows impurity concentration distributions by implanting an impurity in forming the diffusion layer 28. It indicates that ion implantation to the region under the source region 7 is performed.

By the ion implantation in forming the diffusive layer 28, P-type impurity concentration distributions become ones shown by a curve f of FIG. 5. That is, as shown by the curve f, forming the diffusive layer 28 increases an impurity concentration under the source region 7, thereby forming a sufficiently high electric potential barrier to electrons.

Also, under the source region 7, there is a small change in concentration distribution in the horizontal direction of the modulation well 5, and therefore a junction FET is not formed. Thus the transistor characteristics of the modulation transistor TM can be improved.

FIG. 6 shows transistor characteristics in the present embodiment. Characteristics A in FIG. 6 show the gate voltage (Vg)-source voltage (Vs) characteristics in the darkness; characteristics B, the Vg-Vs characteristics when normal light is incident; characteristics C, the Vg-Vs characteristics when very strong light is incident; characteristics D, the Vg-Vs characteristics in the clear state.

A leakage current path from the N-type well 21′ to the source region 7 is not formed, because a sufficiently high electric potential barrier is obtained by the diffusion layer 28 and a junction FET is not formed under the source region 7. Therefore, as shown in FIG. 6, the modulation transistor TM has the Vg-Vs characteristics relatively excellent in linearity even in the range of a relatively low gate voltage.

As shown in FIG. 6, in a non-selected pixel on which strong light is incident, if a sufficiently low non-selected gate voltage is applied to the pixel, the output level of pixel signals is lower than that of a selected pixel after initialization. Thus, even if each pixel in the same column is connected the common source line 66, pixel signals obtained from the selected pixels can be obtained as pixel signals before and after initialization by applying a sufficiently high selected gate voltage to the ring gate 6 of the modulation transistor TM. That is, even if very strong light is incident, signals before and after initialization based on the selected pixel are obtained in a manner similar to the case where normal bright light is incident, and therefore normal pixel signals according to the amount of incident light can be output to prevent an occurrence of black smear.

Process

Next, a method for manufacturing an element will be described with reference to process drawings of FIGS. 7 and 8. FIGS. 7 and 8 show sections taken in the position of line A-A′ of FIG. 2. In FIGS. 7 and 8, arrows indicate performing ion implantation.

The isolation region 22 for isolating the element is formed, as shown in FIG. 7A, on the prepared P-type substrate 1 by using a predetermined resist mask. Phosphorus (P) ion, for example, is then implanted by using a predetermined resist mask to form the N-type well 21 for the photodiode formation region and the N-type well 21′ for the modulation transistor region. This ion implantation is performed to the extent of reaching a relatively deep position in the photodiode formation region. Then the P-type collection well 4 is formed by ion-implanting boron, for example, onto the surface side of the substrate 1 with the use of a predetermined resist mask. The gate oxide film 31 is also formed on the substrate 1 by thermal oxidation.

Subsequently, a P-type impurity is ion-implanted deep into the modulation transistor formation region by using a predetermined resist mask to form the P-type buried layer 23. By the use of the same resist mask, a P-type impurity is shallowly ion-implanted to form the P-type modulation well 5 on the surface layer of the N-type well 21′. Furthermore, by the use of the same resist mask, the N-type diffusion layer 27 for obtaining a channel of the modulation transistor TM is formed in the vicinity of the surface of the substrate on the carrier pocket 10.

As shown in FIG. 7C, the carrier pocket 10 made of a dense P⁺ diffusive layer is formed in the portion under the ring gate 6 of the modulation well 5. As shown in FIG. 7D, the ring gate 6 of the modulation transistor is then formed on the gate oxide film 31.

As shown in FIG. 8A, a N-type impurity is ion-implanted by using a resist mask (not shown) that covers the photodiode formation region and the ring gate 6 as masks to form the drain region 8. The N-type diffusion layer 32 is also formed on the surface of the substrate in the photodiode formation region.

As shown in FIG. 8B, a resist mask 35 that covers the photodiode formation region is formed; an N⁺ impurity with the use of phosphorus is implanted by using the resist mask 35 and the ring gate 6 as masks, thereby forming the source region 7.

Additionally, in the present embodiment, a P-type impurity such as boron is implanted with the use of the resist mask 35 and the ring gate 6 as masks. The impurity is implanted into the area beneath the source region 7. The P-type diffusion layer 28 is thereby formed beneath the source region 7. Incidentally, the concentration of the diffusion layer 28 needs to be set in consideration of the height of an electric potential barrier and a potential gradient. For example, the concentration is set to be higher than or equal to that of the modulation well 5 and lower than or equal to that of the carrier pocket 10.

Thus, in the present embodiment, formation of the P-type diffusion layer 28 in the portion beneath the source region 7 of the modulation well 5 blocks formation of the junction FET between the N-type well 21′ and the source region 7 to prevent a path of a leakage current from being formed between the N-type well 21′ and the source region 7. It is also possible to make an occurrence of a leakage current difficult by increasing the P-type impurity concentration in the portion under the source region 7 of the modulation well 5 that has the potential to become a leakage path between the drain and the source. Therefore, an occurrence of black smear can be prevented and picture quality can be improved.

Incidentally, although an example where the diffusion layer 28 is formed after the source region 7 is formed has been described with reference to FIG. 8, the source region 7 may be formed after the diffusion layer 28 is formed.

### Second Embodiment

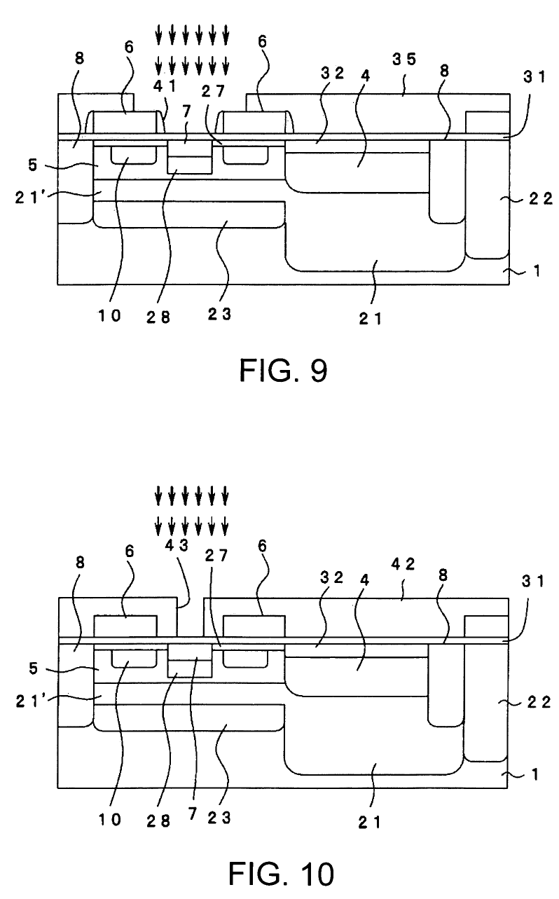

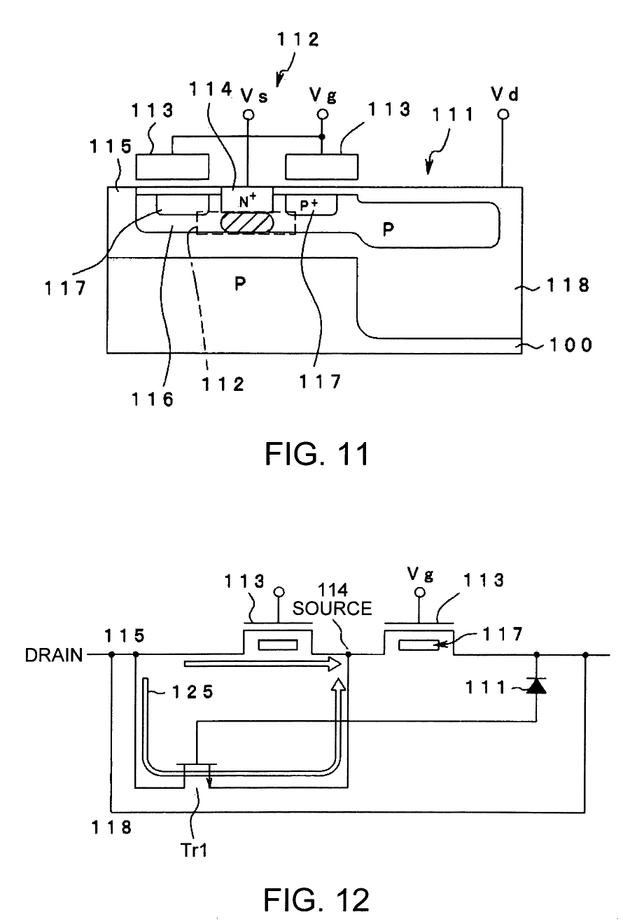

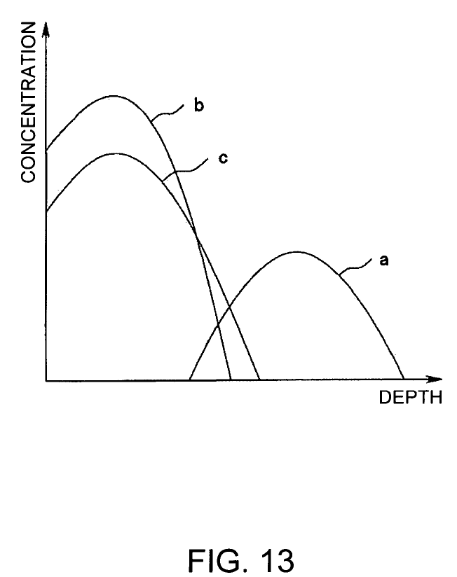

FIGS. 9 and 10 are explanatory views for explaining a manufacturing method according to a second embodiment of the present invention. In FIGS. 9 and 10, the same reference numerals as those in FIG. 8 are attached to the same elements as those in FIG. 8.

In the manufacturing method of FIG. 8, although an example where the source region 7 and the diffusion layer 28 are formed after the ring gate 6 is formed has been described, the source region 7 and the diffusion layer 28 may be formed after formation of a sidewall or contact etching.

FIG. 9 explains an example where the source region 7 and the diffusion layer 28 are formed after a sidewall is formed.

By formation of an insulation layer (not shown) that covers the ring gate 6 and anisotropic etching of the insulation layer, a sidewall 41 is formed on a sidewall of the ring gate 6. The resist mask 35 that covers the photodiode formation region is formed in the area other than the ring gate including the sidewall 41. An N⁺ impurity with the use of phosphorus is implanted and boron is ion-implanted with the resist mask 35 and the ring gate 6 including the sidewall 41 as masks, thereby forming the source region 7 and the diffusion layer 28.

FIG. 10 explains an example where the source region 7 and the diffusion layer 28 are formed after a contact hole is opened.

An interlayer insulation layer 42 is formed in the entire area that covers the modulation transistor formation region and the photodiode formation region after the ring gate 6 is formed (see FIG. 7D). In order to make a wiring layer (not shown) formed on the interlayer insulation layer 42 in contact with the source region 7, a portion of the interlayer insulation layer 42 located corresponding to the source region is opened by etching to form a contact hole 43.

Then an N⁺ impurity with the use of phosphorus is implanted and boron is ion-implanted through the contact hole 43 by using the interlayer insulation layer 42 as a mask, thereby forming the source region 7 and the diffusion layer 28.

Other structures and operation of the present embodiment are substantially similar to those of the first embodiment. In the present embodiment, similar effects as those in the first embodiment can be obtained.

1. A solid-state imaging device including a photoelectric conversion element and a transistor formed adjacent to the photoelectric conversion element, the solid-state imaging device comprising:
a substrate of one conductivity type;
a first well of reverse conductivity type formed on the substrate in a region for forming the photoelectric conversion element;
a second well of one conductivity type formed on the first well;
a third well of reverse conductivity type formed on the substrate in a region for forming the transistor and adjacent to the first well;
a fourth well of one conductivity type formed on the third well and adjacent to the second well;
a gate electrode with an opening formed above the fourth well;
a source formed under the opening;
a drain formed away from the source and electrically connected to the third well; and
at least a first diffusion layer of one conductivity type formed between the source and the third well.

2. The solid-state imaging device according to claim 1, wherein the first diffusion layer constitutes an electric potential barrier of a current path from the third well to the source.

3. The solid-state imaging device according to claim 1, further comprising a second diffusion layer under the gate electrode and in the fourth well, the layer having an impurity concentration higher than that of the fourth well.

4. The solid-state imaging device according to claim 1, wherein the first diffusion layer is formed to have a concentration substantially the same as or higher than that of the third well.
